(19) United States
(12) Patent Application Publication
(10) Pub. No.: US 2019/0204367 A1
(43) Pub. Date: Jul. 4, 2019

(54) SHUNT CURRENT MEASUREMENT FEATURING TEMPERATURE COMPENSATION

(71) Applicant: CONTINENTAL AUTOMOTIVE GMBH, Hannover (DE)

(72) Inventors: Henryk Frenzel, Regensburg (DE); Andreas Aumer, Burglengenfeld (DE)

(73) Assignee: CONTINENTAL AUTOMOTIVE GMBH, Hannover (DE)

(21) Appl. No.: 15/305,979

(22) PCT Filed: Apr. 24, 2015
(86) PCT No.: PCT/EP2015/058963

§ 371 Date: Oct. 21, 2016

(30) Foreign Application Priority Data
Apr. 24, 2014 (DE) 10 2014 207 756.7

(51) Int. Cl. G01R 19/32; G01R 1/20; G01R 19/00

(52) U.S. Cl. CPC G01R 19/32; G01R 19/0092; G01R 1/203

(57) ABSTRACT

A method for measuring an electric current supplied by a vehicle battery and conducted across a shunt includes detecting a measurement voltage drop across the shunt. The method also includes determining a difference in temperature between two temperature points between which at least part of the shunt is located and which are at a distance from one another in the direction of flow of the electric current. The method further includes determining the electric current on the basis of the detected measurement voltage and the determined difference in temperature.

### TECHNICAL FIELD

The invention relates to a method for measuring a current using a current sensor.

### BACKGROUND

Electrical currents in and from a vehicle battery are measured in DE 10 2009 044 992 A1 and in DE 10 2004 062 655 A1, for example, using a current sensor via a measuring resistor, also called shunt. In order to increase the accuracy of the current measurement, it is proposed in both cases to compensate for a temperature increase caused by the power loss dropped across the measuring resistor in order to avoid thermoelectric voltages. For this purpose, the temperature increase is inferred from the power loss.

The object is to improve the known current measurement method.

The object is achieved by means of the features of the independent claims. The dependent claims relate to preferred developments.

According to one exemplary embodiment, a method for measuring an electrical current delivered from a vehicle battery and conducted via an electrical measuring resistor comprises the steps of recording an electrical measurement voltage dropped across the measuring resistor; determining a temperature difference between two temperature points which are spatially at a distance in the direction of flow of the electrical current and between which at least one part of the electrical measuring resistor lies; and determining the electrical current based on the recorded electrical measurement voltage and the determined temperature difference.

The stated method is based on the consideration that the compensation for temperature changes mentioned at the outset is carried out in order to correct measurement errors. The latter stem from the thermoelectric voltage which distorts the voltage drop caused by the electrical current at the measuring resistor, with the result that the measured electrical current likewise has errors. Although the practice of compensating for the temperature change makes it possible to effectively reduce the errors during current measurement, temperature changes in principle spread very slowly. This results in the temperature always being compensated for only with a certain delay or dead time. However, this is not clear from the measured value for the measured current, which is why the current is still incorrectly recorded during the dead time.

The stated method attacks here with the consideration of not compensating for the cause of the incorrect current measurement, that is to say the temperature change, but rather compensating for its effects, that is to say the thermoelectric voltage itself. A current sensor equipped with a measuring resistor records the current to be measured on the basis of a voltage drop across the measuring resistor, the current to be measured being able to be clearly determined using known electrical laws on the basis of the electrical properties of the measuring resistor and the recorded voltage drop. In addition, the underlying cause of the thermoelectric voltage, that is to say the temperature difference, is determined via two points in the measurement section which are locally at a distance. When calculating the electrical current based on the voltage drop, the temperature difference can then be taken into account in order to correct the electrical current.

Correcting the electrical current on the basis of the determined temperature difference makes it possible to remove the thermoelectric voltage from the measured current immediately without a dead time, as a result of which error-free measurement data are available more quickly.

Although the electrical current can be corrected on the basis of the determined temperature difference in any desired manner, the stated method comprises, in one preferred development, the steps of determining an electrical correction voltage based on the determined temperature difference; correcting the electrical measurement voltage based on the electrical correction voltage; and determining the electrical current based on the corrected electrical measurement voltage. The electrical correction voltage should expediently be connected to the thermoelectric voltage explained above and should approximate the latter as closely as possible. The recorded voltage drop, that is to say the electrical measurement voltage, can then be corrected with the thermoelectric voltage by applying the correction voltage to the electrical measurement voltage in a technically simple manner, which saves computing resources, in particular.

In this case, the electrical correction voltage can be determined in any desired manner For example, physical laws can be used to determine the electrical correction voltage analytically or numerically on the basis of the determined temperature difference. However, this is generally possible with an acceptable amount of effort only with difficulty. Therefore, in one preferred development of the stated method, the electrical correction voltage is plotted against the determined temperature difference in a characteristic curve. The electrical correction voltage can then be read from this characteristic curve on the basis of the temperature difference. The characteristic curve can be determined in advance by computation and/or experiments, for example, by entering a defined temperature difference at the measuring resistor and determining the resulting thermoelectric voltage. The characteristic curve can then be stored in a memory with little effort and can be read in real time during use.

The temperature difference between the temperature points can be determined in any desired manner in principle. For this purpose, the temperatures at the two temperature points can be estimated and/or measured, for example, and the temperature difference can then be determined by subtracting the two determined temperatures from one another. In this case, the temperature at only one temperature point can also be measured, for example, and the temperature at the other temperature point can be estimated.

In an additional development of the stated method, the temperature points lie upstream and downstream of the electrical measuring resistor in the direction of flow of the electrical current. In this manner, all material line transitions in the current line, at which a thermoelectric voltage can occur in principle, are concomitantly incorporated in the stated method, with the result that the electrical current can be determined in a particularly accurate manner using the stated method. However, it suffices, in principle, if the temperature difference is recorded only using a single material line transition in order to reduce errors in the measured electrical current using the method.

In another development of the stated method, at least one temperature point is arranged on the surface of an electrical conductor carrying the electrical current, with the result that the determined temperature difference is particularly close to the temperature difference relevant to the thermoelectric voltage and the error in the measured electrical current can therefore be reduced further.

In another development of the stated method, the temperature is optically recorded on the surface of the electrical conductor carrying the electrical current. In particular, it is possible to use recording using infrared sensors in this case. In this manner, the temperature can be contactlessly recorded on the surface and the temperature difference can be measured in an accordingly accurate manner.

In particular, if the temperature is not directly recorded on the surface of the electrical conductor through which current to be measured flows, in order to determine the temperature difference between the temperature points, a temperature at at least one temperature point can be measured and can be delayed by a predetermined dead time before determining the temperature difference. This takes into account the delay during heat propagation on account of the not infinitely high thermal conductivity of the individual components of the current sensor, for example the connection pins, the printed circuit board and/or the air.

In yet another development of the stated method, the temperature at both temperature points is measured and is amplified using a differential amplifier in order to determine the temperature difference between the temperature points. In this manner, the temperature difference is recorded with a sufficiently high amplitude, thus achieving a high signal-to-noise ratio and reducing measurement errors.

According to another exemplary embodiment, a control apparatus is set up to carry out a method as claimed in one of the preceding claims.

In one development of the stated control apparatus, the stated apparatus has a memory and a processor. In this case, the stated method is stored in the memory in the form of a computer program and the processor is intended to carry out the method when the computer program is loaded from the memory into the processor.

According to another exemplary embodiment, a computer program comprises program code means for carrying out all steps of one of the stated methods when the computer program is executed on a computer or one of the stated apparatuses.

According to another exemplary embodiment, a computer program product contains a program code which is stored on a computer-readable data storage medium and, when executed on a data processing device, carries out one of the stated methods.

According to exemplary embodiment, a current sensor for measuring an electrical current comprises an electrical measuring resistor, via which the electrical current to be measured can be carried, and one of the stated control apparatuses.

According to another exemplary embodiment, a vehicle comprises one of the stated control apparatuses and/or the stated current sensor.

### BRIEF DESCRIPTION OF THE DRAWINGS

The above-described properties, features and advantages of the disclosed subject matter and the manner in which they are achieved become clearer and more distinctly comprehensible in connection with the following description of the exemplary embodiments which are explained in more detail in connection with the drawings, in which:

FIG. 1 shows a basic illustration of a vehicle having an electrical drive;

FIG. 2 shows a basic illustration of a current sensor from the vehicle in FIG. 1;

FIG. 3 shows a circuit diagram of the current sensor in FIG. 2; and

FIG. 4 shows changes in the current measurement results from the current sensor in FIG. 3 against the temperature.

In the figures, identical technical elements are provided with identical reference symbols and are described only once.

### DETAILED DESCRIPTION

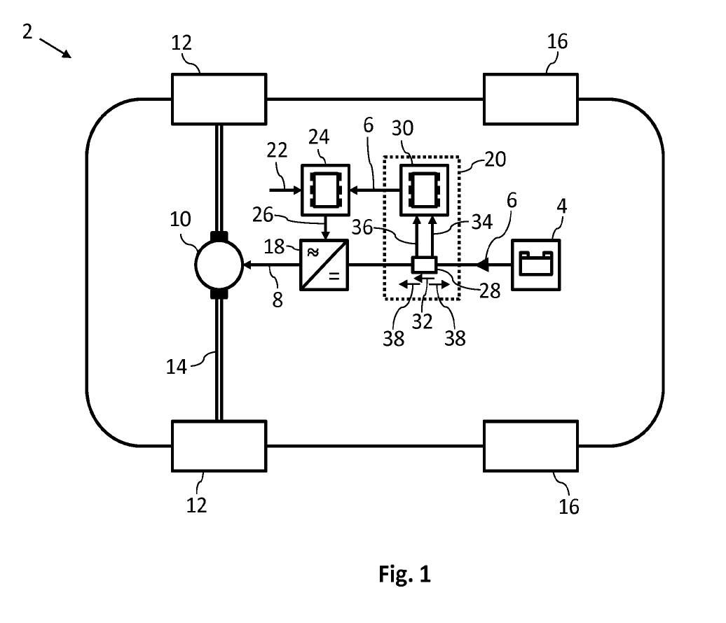

Reference is made to FIG. 1 which shows a basic illustration of a vehicle 2 having a vehicle battery 4 from which an electrical current 6 is delivered.

Various electrical loads in the vehicle 2 are supplied with electrical energy 8 using the electrical current 6.

One example of these electrical loads is an electric motor 10 which uses the electrical energy 8 to drive the front wheels 12 of the vehicle 2 via a drive shaft 14. The rear wheels 16 of the vehicle 2 are therefore free-running wheels. Such electric motors 10 which are used to drive the vehicle 2 are generally in the form of AC motors, whereas the electrical current 6 from the vehicle battery 4 is a direct current. In this case, the electrical current 6 must first of all be converted into an alternating current via a converter 18.

A current sensor 20 which measures the electrical current 6 delivered by the vehicle battery 4 is generally installed in vehicles, such as the vehicle 2. Various functions can then be implemented on the basis of the measured electrical current 6. These functions include, for example, protective functions, as are known from DE 20 2010 015 132 U1, which can be used to protect the vehicle battery 4 from a deep discharge, for example.

If the current 6 measured using the current sensor 2 corresponds only to the electrical current supplied to the converter 18, this current can also be used to control the drive power of the vehicle 2. The drive power is generally predefined by the driver of the vehicle 2 with a driver's request 22. A motor controller 24 then compares an electrical desired current resulting from the driver's request with the measured electrical current 6 and controls the converter 18 using control signals 26 in such a manner that the measured electrical current 6 is adjusted to the desired current resulting from the driver's request. Such control operations are very well known and shall therefore not be enlarged upon any further.

The current sensor 20 comprises a measuring sensor which is preferably in the form of a measuring resistor 28, also called a shunt, and an evaluation device 30. Within the scope of the present embodiment, the electrical current 6 flows through the measuring resistor 28, which results in a voltage drop 32 across the measuring resistor 28. This voltage drop 32 is recorded as a measurement voltage by the evaluation device 30 using an input-side electrical potential 34, as seen in the direction of the electrical current 6, at the measuring resistor 28 and an output-side electrical potential 36 at the measuring resistor 28. The evaluation device 30 uses these two electrical potentials 34, 36 to calculate the voltage drop 32 and uses the resistance value of the measuring resistor 28 to calculate the electrical current 6 flowing through the measuring resistor 28.

The measuring resistor 28, as an electrical conductor, generally differs from the other electrical conductors which carry the electrical current 6 from the vehicle battery 4 to the converter 18. As is known, the thermoelectric effect, also called Seebeck effect, causes a thermoelectric voltage at a material transition in an electrical conductor, which lies in a temperature gradient, that is to say a temperature difference. On account of the measuring resistor 28 on the current sensor 20, such a material transition is present on the input side and on the output side. A temperature difference is produced, in principle, because the measuring resistor 28 is heated on account of electrical power losses caused by the electrical current 6. The thermoelectric voltages 38 produced in this manner are added to the voltage drop 32 and therefore distort the measurement of the electrical current 6.

Therefore, within the scope of the present embodiment, it is proposed to correct the measurement of the electrical current 6 with the thermoelectric voltages 38. Within the scope of the present embodiment, this is carried out inside the evaluation device 30 and shall be described below:

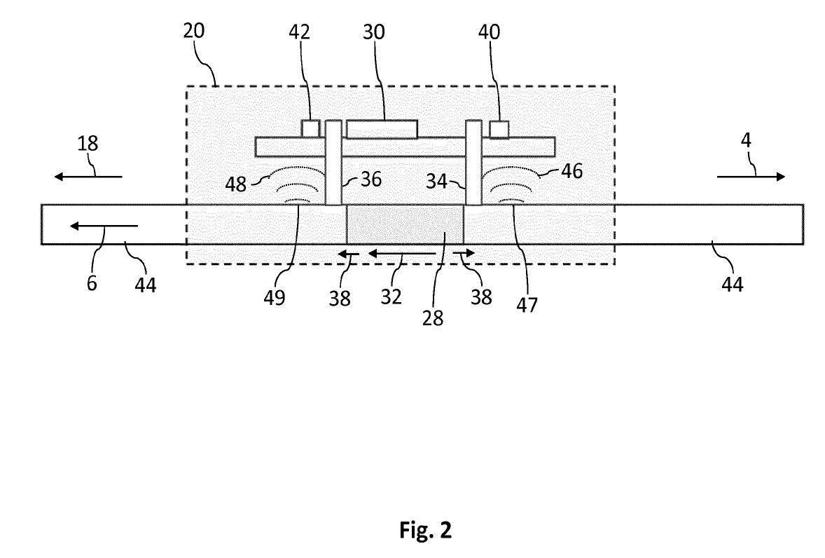

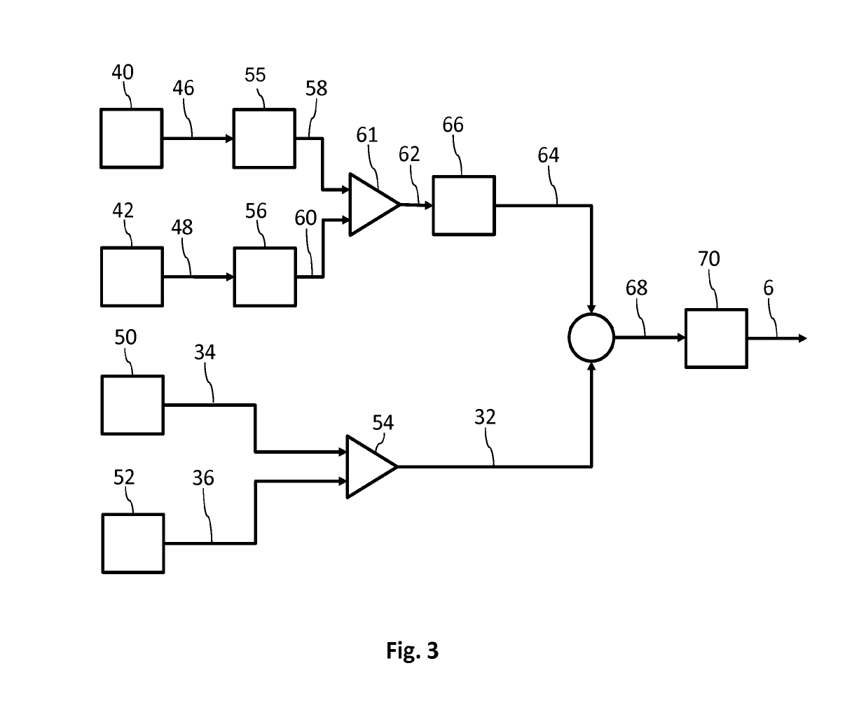

Reference is made to FIGS. 2 and 3 which accordingly show the current sensor 20 in a schematic illustration according to a first exemplary embodiment and a flowchart which can be carried out when measuring the current 6 in the current sensor 20.

Within the scope of the present embodiment, a first temperature sensor 40 and a second temperature sensor 42 are arranged on the current sensor 20 and accordingly measure the temperature 46, 48 of the conductor 44 carrying the electrical current at a temperature point 47 upstream of the measuring resistor 28 and at a temperature point 49 downstream of the measuring resistor 28 in the direction of the electrical current 6.

In order to measure the current 6, the two electrical potentials 34, 36 can first of all be measured using corresponding voltmeters 50, 52 which measure the electrical potentials 34, 36 as an electrical voltage with respect to a reference potential, for example ground. The measured electrical potentials 34, 36 can then be subtracted from one another and simultaneously amplified in a differential amplifier 54, for example an operational amplifier, and the voltage drop 32 can therefore be calculated. In this manner, the voltage drop 32 is available as a basis for determining the electrical current 6.

As already explained, however, this voltage drop should be corrected with the thermoelectric voltages 38 before determining the electrical current 6. For this reason, the input-side temperature 46 and the output-side temperature 48 are recorded at the measuring resistor 28. Since the spreading of the temperatures 46, 48 to the corresponding temperature sensors 40, 42 takes a certain amount of time, delay elements 55, 56 which delay the measured temperatures 46, 48 by these delay times are also present within the scope of the present embodiment. So that the delay times, also called dead times, can be individually set for each temperature 46, 48, a separate delay element 55, 56 is arranged for each temperature 46, 48.

The accordingly delayed temperatures 58, 60 are then subtracted from one another using a differential amplifier 61, for example, with the result that the temperature difference 62 between the measurement points at which the temperatures 46, 48 were measured is known.

A correction voltage 64 which is dependent on the two thermoelectric voltages 38 is finally determined from this temperature difference 62. In the present exemplary embodiment, a characteristic curve 66 is present for this purpose, within the scope of which a correction voltage 64 is uniquely assigned to each temperature difference 62. This characteristic curve 66 can be determined in advance by means of experiments and/or analytically, for example. In order to determine the characteristic curve 66 by means of experiments, the voltage drop 32 across the measuring resistor 28 can be measured as the correction voltage 64 on a trial basis, for example, without the current 6 flowing through the measuring resistor 28.

The correction voltage 64 is then applied to the voltage drop 32 for the purpose of correction. The voltage drop 68 corrected in this manner can then be converted into the current 6 sought in a manner known per se in a corresponding conversion device 70.

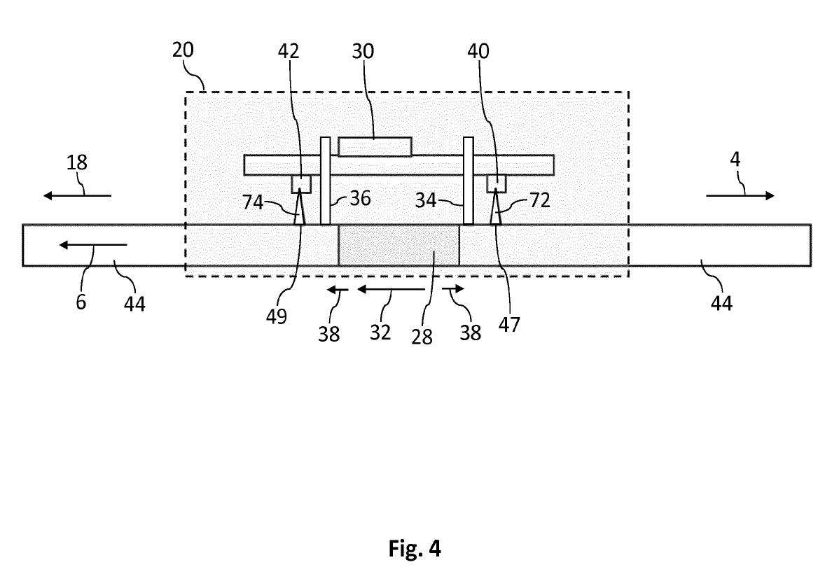

Within the scope of the current sensor 20 shown in FIG. 4, the temperatures 46, 48 can also be optically recorded, for example, directly at the surface of the electrical conductor 44. For this purpose, the temperature sensors 40, 42 are in the form of optical sensors and, in particular, in the form of infrared sensors which record the temperatures 46, 48 using corresponding infrared radiation 72, 74 caused by the temperatures 46, 48.

In this manner, the temperatures 46, 48 are recorded immediately in terms of time, thus possibly making it possible to entirely dispense with the delay elements 54, 56 shown in FIG. 3.

1. A method for measuring an electrical current delivered from a vehicle battery and conducted via a measuring resistor, comprising:
recording a voltage drop across the measuring resistor;
determining a temperature difference between two temperature points which are spatially at a distance in the direction of flow of the electrical current and between which at least one part of the electrical measuring resistor lies; and
determining the electrical current based on the recorded voltage drop and the determined temperature difference.

2. The method as claimed in claim 1, comprising:
determining an electrical correction voltage based on the determined temperature difference;
correcting the voltage drop based on the electrical correction voltage; and
determining the electrical current based on the corrected voltage drop.

3. The method as claimed in claim 2, the electrical correction voltage being plotted against the determined temperature difference in a characteristic curve.

4. The method as claimed in claim 1, the temperature points lying upstream and downstream of the measuring resistor in the direction of flow of the electrical current.

5. The method as claimed in claim 4, at least one temperature point being arranged on a surface of an electrical conductor carrying the electrical current.

6. The method as claimed in claim 5, a temperature on which the temperature difference is based being optically recorded on the surface of the electrical conductor carrying the electrical current.

7. The method as claimed in claim 1, wherein, in order to determine the temperature difference between the temperature points, a temperature at at least one temperature point is measured and is delayed by a predetermined dead time before determining the temperature difference.

8. The method as claimed in claim 1, a temperature at both temperature points being measured and being amplified using a differential amplifier in order to determine the temperature difference between the temperature points.

9. (canceled)

10. A current sensor for measuring an electrical current, comprising:
a measuring resistor via which the electrical current to be measured can be carried,
a pair of voltmeters configured to measure electrical voltages across the measuring resistor,
a first differential amplifier in communication with the pair of voltmeters and configured to determine a voltage drop across the measuring resistor,
a first temperature sensor configured to measure a a temperature of a conductor carrying the electrical current upstream of the measuring resistor at a first measurement point,
a second temperature sensor configured to measure a temperature of the conductor carrying the electrical current downstream of the measuring resistor at a second measurement point,
a second differential amplifier electrically in communication with said first and second temperature sensors and configured to determine a temperature difference between the first and second measurement points, and
a conversion device in communication with the first and second differential amplifiers and configured to determine the electrical current based on the voltage drop and the determined temperature difference.
